(19) United States
(12) Patent Application Publication
(10) Pub. No.: US 2014/0231746 A1
(43) Pub. Date: Aug. 21, 2014

(54) SEMICONDUCTOR LIGHT EMITTING DEVICE

(71) Applicant: SAMSUNG ELECTRONICS CO., LTD., Suwon-si (KR)

(72) Inventors: Jae Sung HYUN, Hwaseong-si (KR); Hyun Wook SHIM, Suwon-si (KR); Jin Young LIM, Gwacheon-si (KR)

(73) Assignee: SAMSUNG ELECTRONICS CO., LTD., Suwon-si (KR)

(21) Appl. No.: 14/083,101

(22) Filed: Nov. 18, 2013

(30) Foreign Application Priority Data
Feb. 20, 2013 (KR) 10-2013-0018306

(51) Int. Cl. H01L 33/02; H01L 33/32; H01L 33/06

(52) U.S. Cl. CPC H01L 33/025; H01L 33/06; H01L 33/325
USPC 257/13

(57) ABSTRACT

A semiconductor light emitting device includes an n-type semiconductor layer, a p-type semiconductor layer, and an active layer interposed between the n-type semiconductor layer and the p-type semiconductor layer. The p-type semiconductor layer includes a first impurity region including a p-type impurity and a second impurity region including an n-type impurity. The first and second impurity regions are alternately repeated at least once.

### CROSS-REFERENCE TO RELATED APPLICATIONS

This application claims benefit of priority to, and the benefit of, Korean Patent Application No. 10-2013-0018306 filed on Feb. 20, 2013, with the Korean Intellectual Property Office, the entire contents of which are hereby incorporated by reference.

### TECHNICAL FIELD

The present inventive concept relates to a semiconductor light emitting device.

### BACKGROUND

In general, nitride semiconductors are widely used in green or blue light emitting diodes (LEDs) or laser diodes (LDs) provided as light sources in full-color display devices, image scanners, various signaling devices, and optical communications devices. Such nitride semiconductor light emitting devices may be provided as light emitting devices including an active layer emitting light of various colors including blue light and green light through the recombination of electrons and holes.

With the enlargement of the applications of nitride semiconductor light emitting devices, research into light sources for general lighting devices and electronic devices is being actively conducted. In recent years, research has been extended to high current/high output products using light emitting devices. Therefore, research into improvements in semiconductor light emitting devices in terms of light emitting efficiency and quality is being actively conducted. In particular, semiconductor layer structures are being developed in order to improve the quantum efficiency of light emitting devices.

### SUMMARY

An aspect of the present inventive concept provides a semiconductor light emitting device, capable of increasing internal quantum efficiency and improving luminance by increasing a carrier concentration.

An aspect of the present inventive concept relates to a semiconductor light emitting device including an n-type semiconductor layer, a p-type semiconductor layer including a first impurity region including a p-type impurity and a second impurity region including an n-type impurity, the first and second impurity regions being alternately repeated at least once, and an active layer interposed between the n-type semiconductor layer and the p-type semiconductor layer.

The second impurity region may further include the p-type impurity, and a concentration of the p-type impurity in the p-type semiconductor layer may be uniform or gradually varied.

A concentration of the p-type impurity included in the second impurity region may be higher than a concentration of the n-type impurity included in the second impurity region.

The first impurity region may include four first impurity sub-regions. The second impurity region may include three second impurity sub-regions.

The first impurity region may include a plurality of first impurity sub-regions that include intentionally doped and intentionally undoped impurity regions.

The first impurity region may include four first impurity sub-regions, and the first impurity sub-region disposed to be second from the active layer among the four first impurity sub-regions may be the intentionally doped impurity region, and remaining first impurity sub-regions among the four first impurity sub-regions may be the intentionally undoped impurity regions.

The second impurity region may include the n-type impurity in a concentration of 1.0×10¹⁶/cm³ to 1.0×10¹⁸/cm³.

The first impurity region may have a first thickness and the second impurity region may have a second thickness ranging from 2% to 10% of the first thickness.

The first impurity region and the second impurity region may be formed of AlₓIn_{y}Ga_{1-x-y}N (0≦x<1, 0≦y<1).

The first impurity region and the second impurity region may have the same band gap energy.

The n-type impurity may be at least one of silicon (Si) and carbon (C) and the p-type impurity may be at least one of magnesium (Mg) and zinc (Zn).

The p-type semiconductor layer may further include an electron blocking layer disposed to be adjacent to the active layer and having a band gap energy higher than a band gap energy of the first impurity region and the second impurity region.

The electron blocking layer may include a region formed of AlₓIn_{y}Ga_{1-x-y}N (0<x≦1, 0≦y<1).

Another aspect of the present inventive concept encompasses a semiconductor light emitting device including an n-type semiconductor layer, a p-type semiconductor layer including a plurality of n-type impurity regions spaced apart from each other by a predetermined interval, and an active layer interposed between the n-type semiconductor layer and the p-type semiconductor layer. The p-type semiconductor layer has a gradually varied p-type impurity concentration.

In the plurality of n-type impurity regions, a concentration of an n-type impurity may range from 1.0×10¹⁶/cm³ to 1.0×10¹⁸/cm³.

The p-type semiconductor layer may include a plurality of p-type impurity regions spaced apart from each other by a predetermined interval.

Each of the p-type impurity regions may have a thickness greater than a thickness of each of the second impurity regions.

Still another aspect of the present inventive concept relates to a lighting device including a light emitting module that includes a circuit board and a light emitting device disposed on the circuit board, and a heat sink plate in direct contact with the light emitting module. The light emitting device includes an n-type semiconductor layer, a p-type semiconductor layer including a first impurity region including a p-type impurity and a second impurity region including an n-type impurity, and an active layer interposed between the n-type semiconductor layer and the p-type semiconductor layer. The first and second impurity regions are alternately repeated at least once.

The lighting device may include a plurality of heat radiating fins.

The light emitting device may be disposed on the circuit board in the form of a package.

### BRIEF DESCRIPTION OF THE DRAWINGS

The above and other aspects, features and other advantages of the present inventive concept will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a cross-sectional view illustrating a semiconductor light emitting device according to an embodiment of the present inventive concept.

FIG. 2 is an enlarged view illustrating a p-type semiconductor layer employable in the semiconductor light emitting device of FIG. 1.

FIG. 3 is a cross-sectional view illustrating a semiconductor light emitting device according to an embodiment of the present inventive concept.

FIG. 4 is an enlarged view illustrating a p-type semiconductor layer employable in the semiconductor light emitting device of FIG. 3.

FIG. 5 is a cross-sectional view illustrating a semiconductor light emitting device according to an embodiment of the present inventive concept.

FIG. 6 is an enlarged view illustrating a p-type semiconductor layer employable in the semiconductor light emitting device of FIG. 5.

FIGS. 7A through 7C are flow diagrams of impurities introduction for explaining a method of forming a p-type semiconductor layer in a semiconductor light emitting device according to an embodiment of the present inventive concept.

FIG. 8 is a cross-sectional view illustrating a semiconductor light emitting device according to an embodiment of the present inventive concept.

FIG. 9 is a cross-sectional view illustrating a semiconductor light emitting device according to an embodiment of the present inventive concept.

FIGS. 10 and 11 are views respectively illustrating an example of applying a semiconductor light emitting device according to an embodiment of the present inventive concept to a package.

FIGS. 12 and 13 are views respectively illustrating an example of applying a semiconductor light emitting device according to an embodiment of the present inventive concept to a backlight unit.

FIG. 14 is a view illustrating an example of applying a semiconductor light emitting device according to an embodiment of the present inventive concept to a lighting device.

FIG. 15 is a view illustrating an example of applying a semiconductor light emitting device according to an embodiment of the present inventive concept to a headlamp.

### DETAILED DESCRIPTION

Hereinafter, embodiments of the present inventive concept will be described in detail with reference to the accompanying drawings. The present inventive concept may, however, be embodied in many different forms and should not be construed as being limited to the embodiments set forth herein. Rather, these embodiments of the present inventive concept are provided so that this disclosure will be thorough and complete, and will fully convey the scope of the present inventive concept to those skilled in the art. In the drawings, the shapes and dimensions of elements may be exaggerated for clarity, and the same reference numerals will be used throughout to designate the same or like elements.

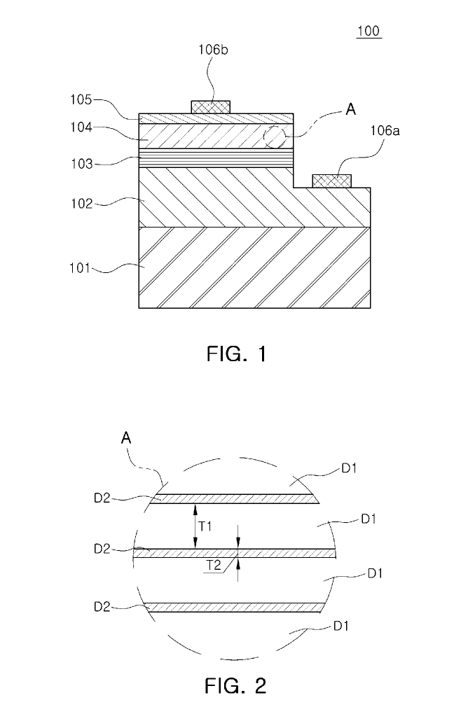

FIG. 1 is a cross-sectional view illustrating a semiconductor light emitting device according to an embodiment of the present inventive concept.

FIG. 2 is an enlarged view illustrating a p-type semiconductor layer employable in the semiconductor light emitting device of FIG. 1. Specifically, FIG. 2 is an enlarged view of region A of FIG. 1.

Referring to FIG. 1, a semiconductor light emitting device 100 according to an embodiment of the present inventive concept may include a substrate 101, an n-type semiconductor layer 102, an active layer 103, a p-type semiconductor layer 104, and an ohmic electrode layer 105. First and second electrodes 106a and 106b may be formed on upper surfaces of the n-type semiconductor layer 102 and the ohmic electrode layer 105, respectively. Unless explicitly described otherwise, the terms ‘upper part’, ‘upper surface’, ‘lower part’, ‘lower surface’, ‘side surface’, and the like, used herein are used based on the drawings, and may actually be different depending on a direction in which a device is actually disposed.

The substrate 101 may be a semiconductor growth substrate and may be formed of an insulating material, a conductive material, or a semiconductor material, such as sapphire, Si, SiC, MgAl₂O₄, MgO, LiAlO₂, LiGaO₂, GaN, or the like. Here, sapphire may be an electrical insulator and crystal having Hexa-Rhombo R3C symmetry.

The sapphire may have a lattice constant of 13.001 Å in a C-axis direction and a lattice constant of 4.758 Å in an A-axis direction and may include a C (0001) plane, an A (1120) plane, an R (1102) plane, and the like. In this case, the C plane may be mainly used as a nitride growth substrate because the C plane relatively facilitates the growth of a nitride film and is stable at high temperatures. However, when the nitride film is grown on the C plane, a high level of electric field may be formed inside the nitride film due to the piezoelectric effect. When the substrate 101 is formed of silicon (Si), since a Si substrate is appropriate for obtaining a substrate having a large diameter and requires relatively low manufacturing costs, mass production thereof may be enhanced.

The n-type and p-type semiconductor layers 102 and 104 may be formed of a nitride semiconductor, a material having a composition of AlₓIn_{y}Ga_{1-x-y}N (0≦x≦1, 0≦y≦1, 0≦x+y≦1). Each of the semiconductor layers 102 and 104 may be formed of a single layer but may also include a plurality of layers having different characteristics such as doping concentrations, compositions or the like. The n-type and p-type semiconductor layers 102 and 104 may be formed using an AlInGaP-based or an AlInGaAs-based semiconductor, in addition to the nitride semiconductor. The active layer 103 disposed between the n-type and p-type semiconductor layers 102 and 104 may emit light having a predetermined degree of energy due to the recombination of electrons and holes and may have a multiple quantum well (MQW) structure in which quantum barrier and quantum well layers are alternately stacked. For example, when the active layer 103 is formed of a nitride semiconductor, a GaN/InGaN structure may be used, but a single quantum well (SQW) structure may also be used.

Meanwhile, the n-type and p-type semiconductor layers 102 and 104 and the active layer 103 may be grown using a semiconductor layer growth process, such as metal organic chemical vapor deposition (MOCVD), hydride vapor phase epitaxy (HYPE), molecular beam epitaxy (MBE), or the like. A buffer layer (not separately shown) capable of alleviating stress acting on the n-type semiconductor layer 102 and improving crystalline properties may be formed on the substrate 101 in advance before the n-type semiconductor layer 102 is formed on the substrate 101.

The p-type semiconductor layer 104 may include first and second impurity regions D1 and D2. The first and second impurity regions D1 and D2 may be formed of a material having the same band gap energy, for example, GaN. In addition, the first impurity region D1 may be formed of a material having a single composition. However, the present inventive concept is not limited thereto and accordingly, the first impurity region D1 may be formed of materials having different compositions. As illustrated in FIG. 2, the p-type semiconductor layer 104 may have a structure in which the first and second impurity regions D1 and D2 are alternately repeated at least once and in particular, the first impurity region D1 may be formed four times. The first impurity region D1 may be a region including a p-type impurity and the second impurity region D2 may be a region including an n-type impurity. The first impurity region D1 may be intentionally doped with the p-type impurity and the second impurity region D2 may be intentionally doped with the n-type impurity. The p-type impurity may be any one of magnesium (Mg) and zinc (Zn) and the n-type impurity may be any one of silicon (Si) and carbon (C).

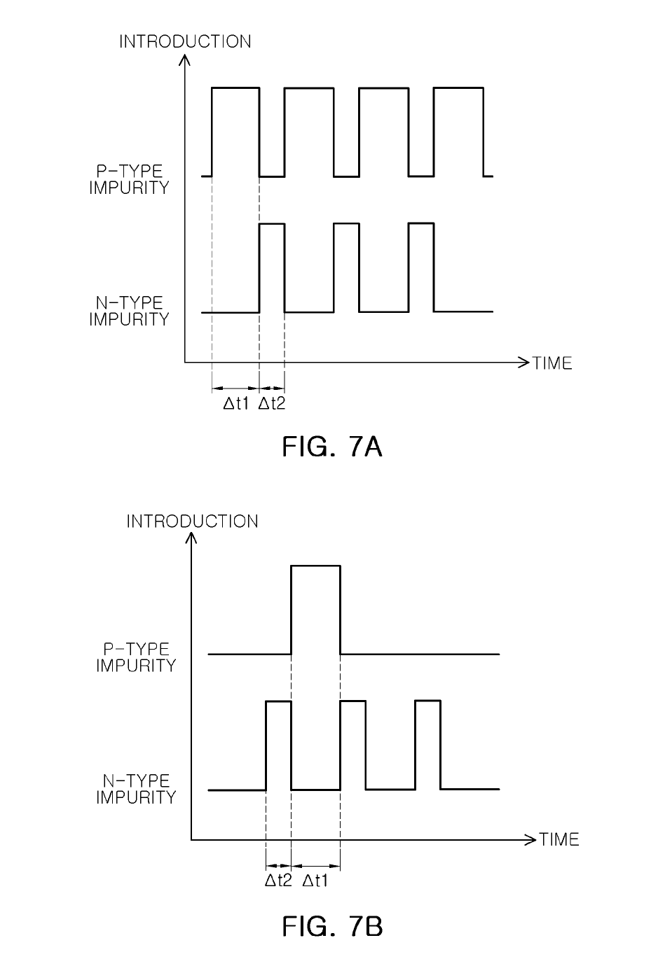

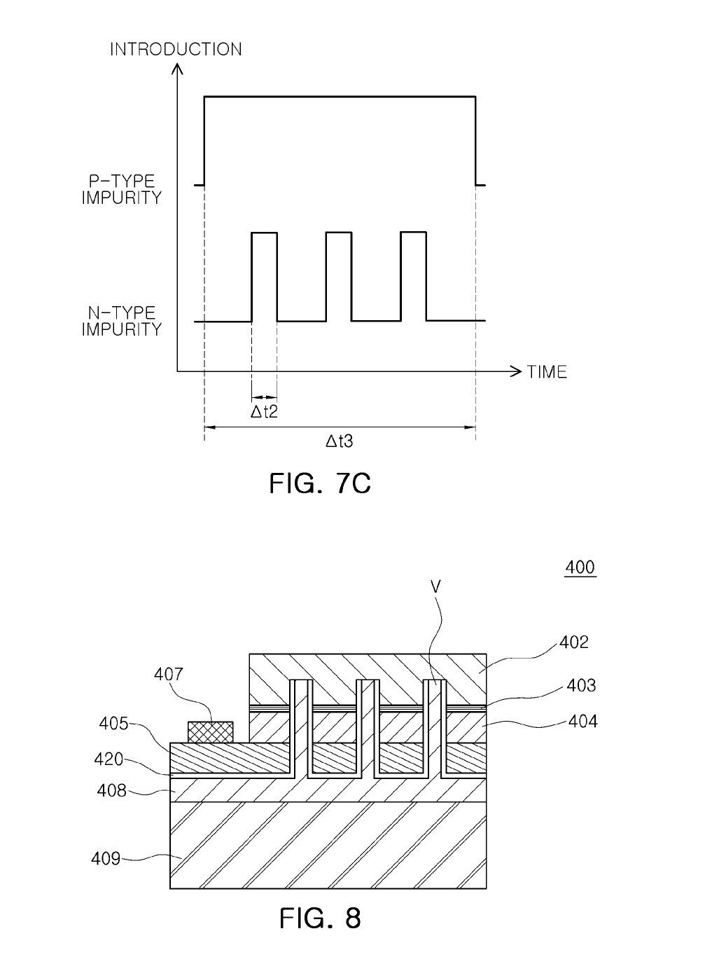

A concentration of the p-type impurity in the first impurity region D1 may range from 1.0×10¹⁸/cm³ to 1.0×10²⁰/cm³. A concentration of the n-type impurity in the second impurity region D2 may range from 1.0×10¹⁶/cm³ to 1.0×10¹⁸/cm³. When the concentration of the n-type impurity is relatively low, e.g., lower than the concentration of the p-type impurity, improvements in quantum efficiency according to an embodiment of the present inventive concept may be insignificantly exhibited. On the other hand, when the concentration of the n-type impurity is relatively high, e.g., higher than the concentration of the p-type impurity, a leakage current may be generated. In an embodiment of the present inventive concept, the first and second impurity regions D1 and D2 may be alternately doped with the p-type impurity and the n-type impurity during the forming of the p-type semiconductor layer 104, and this will be described in detail later with reference to FIG. 7A.

According to an embodiment of the present inventive concept, the first impurity region D1 may also include a small quantity of the n-type impurity diffused from the second impurity region D2 during a manufacturing process of the semiconductor light emitting device 100. In addition, the second impurity region D2 may also include the p-type impurity diffused from the first impurity region D1 during the manufacturing process of the semiconductor light emitting device 100. The concentration of the p-type impurity included in the second impurity region D2 may be similar to that in the first impurity region D1. Thus, the concentration of the p-type impurity in the p-type semiconductor layer 104 may be uniform or gradually varied. In the specification, gradual variations in concentration mean that concentrations have a linear or a nonlinear distribution obtained through diffusion. Thus, the concentration of the p-type impurity in the p-type semiconductor layer 104 may not be rapidly varied. According to an embodiment of the present inventive concept, the concentration of the p-type impurity included in the second impurity region D2 may be higher than that of the n-type impurity in the second impurity region D2.

The first impurity region D1 may have a first thickness T1 and the second impurity region D2 may have a second thickness T2 smaller than the first thickness T1. The second thickness T2 may be determined within a range of 2% to 10% of that of the first thickness T1. The first thickness T1 may range, for example, from 30 nm to 40 nm and the second thickness T2 may range, for example, from 0.6 nm to 4 nm.

As illustrated in FIGS. 1 and 2, the first and second impurity regions D1 and D2 may be repeatedly formed in the p-type semiconductor layer 104, whereby a hole concentration may be increased and holes may be effectively dispersed within the p-type semiconductor layer 104. In general, when the p-type semiconductor layer 104 is doped with magnesium (Mg), magnesium (Mg) may react with hydrogen (H₂), a carrier gas, to form a Mg—H compound during a MOCVD process, thereby causing difficulty in ionization of Mg, whereby it may be difficult to increase the hole concentration to a predetermined level or more. However, an acceptor-donor-acceptor complex may be formed due to the formation of the first and second impurity regions D1 and D2 in an embodiment of the present inventive concept to allow an effective lowering in an acceptor energy level, whereby the hole concentration may be increased and hole mobility may be improved.

Meanwhile, referring to FIG. 1 again, other components will be described. The ohmic electrode layer 105 may be formed of a material that exhibits electrical ohmic-characteristics with the p-type semiconductor layer 104. The ohmic electrode layer 105 may include, for example, p-GaN including a higher concentration of the p-type impurity than a concentration of the p-type impurity of the p-type semiconductor layer 104. Alternatively, the ohmic electrode layer 105 may be formed of a metal such as Ag, Ni, Al, Rh, Pd, Ir, Ru, Mg, Zn, Pt, Au or the like, or a transparent conductive oxide such as ITO, CIO, ZnO or the like. However, the ohmic electrode layer 105 is not necessarily required in an embodiment of the present inventive concept and thus, it may be omitted in some cases.

The first and second electrodes 106a and 106b may be formed through a process of deposition of an electrical conductive material, for example, at least one of Ag, Al, Ni, Cr and the like. In the case of a structure shown in FIG. 1, although the first and second electrodes 106a and 106b are formed on the upper surfaces of the n-type semiconductor layer 102 and the ohmic electrode layer 105, respectively, such a formation method of the electrodes 106a and 106b may be provided by way of an example.

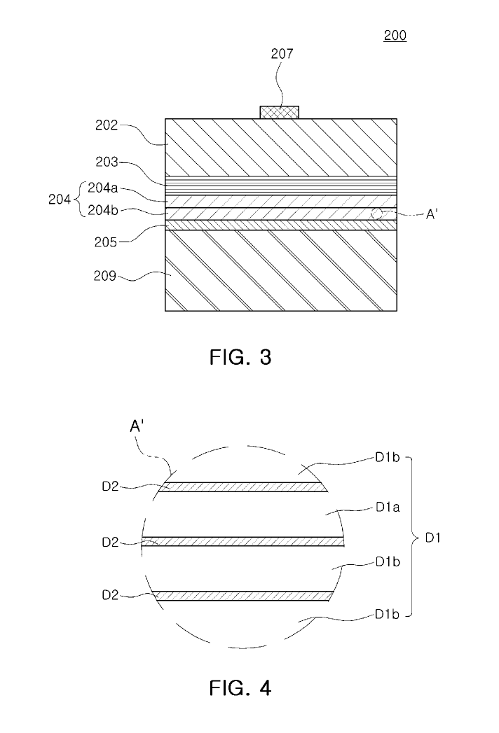

FIG. 3 is a cross-sectional view illustrating a semiconductor light emitting device according to an embodiment of the present inventive concept.

FIG. 4 is an enlarged view illustrating a p-type semiconductor layer employable in the semiconductor light emitting device of FIG. 3. Specifically, FIG. 4 is an enlarged view of region A′ of FIG. 3.

Referring to FIG. 3, in a semiconductor light emitting device 200, a light emitting structure may be formed on the conductive substrate 209. The light emitting structure may include an n-type semiconductor layer 202, an active layer 203, and a p-type semiconductor layer 204. In this case, the p-type semiconductor layer 204 may include an electron blocking layer 204a and a clad layer 204b. In addition, an n-type electrode 207 may be formed on the n-type semiconductor layer 202, and a reflective metal layer 205 and the conductive substrate 209 may be formed under the p-type semiconductor layer 204.

In an embodiment of the present inventive concept, the p-type semiconductor layer 204 may include the electron blocking layer 204a and the clad layer 204b. The electron blocking layer 204a may serve to block electrons introduced from the active layer 203 so as to increase recombination efficiency within the active layer 203 and in order to this, may be formed of a material having a band gap energy higher than a band gap energy of a material forming the clad layer 204b. In addition, the electron blocking layer 204b may have a structure in which a plurality of layers having different compositions of AlₓIn_{y}Ga_{1-x-y}N (0<x≦1, 0≦y<1) are staked. Specifically, a multiple layer structure including a single AlGaN layer or AlGaN, a super-lattice structure of AlGaN/GaN, or the like may be used.

The clad layer 204b may include the first and second impurity regions D1 and D2, and the first impurity region D1 may be provided in plural and the plurality of first impurity regions D1 may include an intentionally doped impurity region D1a and an intentionally undoped impurity region D1b. The first impurity region D1 refers to a region including a p-type impurity and the second impurity region D2 refers to a region including an n-type impurity.

As illustrated in FIG. 4, the clad layer 204b may have a structure in which the first and second impurity regions D1 and D2 are alternately repeated at least once and in particular, the first impurity region D1 may be formed four times. In this case, the first impurity region D1 disposed to be second from the active layer 203, among four first impurity regions D1, may be the doped impurity region D1a, and the remaining first impurity regions D1 may be the undoped impurity regions D1b. The undoped impurity region D1b may include the p-type impurity diffused from the doped impurity region D1a. In an embodiment of the present inventive concept, the first and second impurity regions D1 and D2 may be doped with the p-type impurity once, and with the n-type impurity three times, respectively, during the forming of the clad layer 204b. This will be described in detail with reference to FIG. 7B.

At least one structure of the electron blocking layer 204a and the clad layer 204b may also be applied to the semiconductor light emitting device of FIG. 1.

The reflective metal layer 205 may be formed of a material that exhibits electrical ohmic-characteristics with the p-type semiconductor layer 204. The reflective metal layer 205 may be further formed of a metal having a high degree of reflectance in order to reflect light emitted from the active layer 203. The reflective metal layer 205 may include Ag, Ni, Al, Rh, Pd, Ir, Ru, Mg, Zn, Pt, Au or the like in consideration of the function thereof.

The conductive substrate 209 may be connected to an external power source and may serve to apply an electrical signal to the p-type semiconductor layer 204. In addition, the conductive substrate 209 may serve as a support supporting the light emitting structure in a process for removing a substrate used in semiconductor growth, such as a laser lift off process or the like, and may be formed of a material including one of Au, Ni, Al, Cu, W, Si, Se and GaAs, for example, may be a Si substrate doped with aluminum (Al). In this case, the conductive substrate 209 may be formed on the reflective metal layer 205 through a process such as a plating process, a sputtering process or the like. Alternately, the conductive substrate 209 may be previously manufactured and then be bonded to the reflective metal layer 205 through a conductive bonding layer.

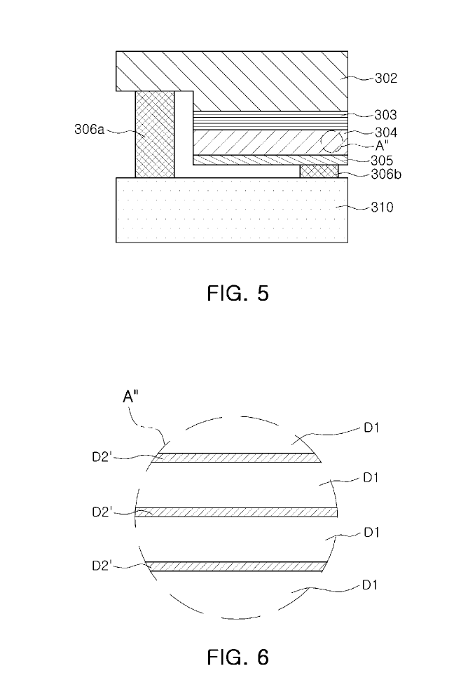

FIG. 5 is a cross-sectional view illustrating a semiconductor light emitting device according to an embodiment of the present inventive concept.

FIG. 6 is an enlarged view illustrating a p-type semiconductor layer employable in the semiconductor light emitting device of FIG. 5. Specifically, FIG. 6 is an enlarged view of region A″ of FIG. 5.

Referring to FIG. 5, a semiconductor light emitting device 300 according to an embodiment of the present inventive concept may include a package substrate 310 and a light emitting structure formed on the package substrate 310. The light emitting structure may include an n-type semiconductor layer 302, an active layer 303, and a p-type semiconductor layer 304, and first and second electrodes 306a and 306b may be formed on lower surfaces of the n-type semiconductor layer 302 and an ohmic electrode layer 305, respectively. The semiconductor light emitting device 300 according to an embodiment of the present inventive concept may have a flip chip structure in which the first and second electrodes 306a and 306b are mounted towards the package substrate 310.

In an embodiment of the present inventive concept, the p-type semiconductor layer 304 may include first and second impurity regions D1 and D2′. The first impurity region D1 may be a region including a p-type impurity and the second impurity region D2 ‘may be a region including an n-type impurity. The first impurity region D1 may be intentionally doped with the p-type impurity and the second impurity region D2’ may be intentionally doped with the n-type impurity. In particular, the second impurity region D2′ may include the p-type impurity in addition to the n-type impurity, and all of the n-type impurity and the p-type impurity may be provided by a doping method in an embodiment of the present inventive concept. As illustrated in FIGS. 5 and 6, the first and second impurity regions D1 and D2′ may be formed by continuously doping the p-type semiconductor layer 304 with the p-type impurity while doping the second impurity region D2′ with the n-type impurity three times during the doping of the p-type semiconductor layer 304. This will be described in detail with reference to FIG. 7C.

The structure of the p-type semiconductor layer 304 according to an embodiment of the present inventive concept may also be applied to the p-type semiconductor layer 104 of the semiconductor light emitting device 100 of FIG. 1 and the clad layer 204b of the semiconductor light emitting device 200 of FIG. 3.

The ohmic electrode layer 305 may formed of a light reflective material, for example, a highly reflective metal. The ohmic electrode layer 305 may include, for example, Ag, Ni, Al, Rh, Pd, Ir, Ru, Mg, Zn, Pt, Au or the like.

The package substrate 310 may have the light emitting structure mounted on a surface thereof and may be provided as a circuit board such as printed circuit board (PCB), metal-core printed circuit board (MCPCB), multilayer printed circuit board (MPCB), flexible printed circuit board (FPCB) or the like, a ceramic substrate such as AlN, Al₂O₃ or the like, or a Si substrate. In addition, the package substrate 310 may be provided in the form of a package lead frame, rather than in the form of a substrate.

FIGS. 7A through 7C are flow diagrams of impurities introduction for explaining a method of forming the p-type semiconductor layer in the semiconductor light emitting device according to an embodiment of the present inventive concept.

In FIGS. 7A through 7C, a vertical axis indicates p-type and n-type impurities introduced during a process of forming the p-type semiconductor layer or carrier gases including the impurities, and a horizontal axis indicates introduction times.

Referring to FIG. 7A, a flow diagram of impurities introduced into the p-type semiconductor layer 104 is illustrated. The p-type impurity may be introduced for a first interval of time Δt1, the n-type impurity may be introduced for a second interval of time Δt2, and the introductions of the p-type and the n-type impurities may be alternately repeated. The p-type impurity may be introduced for the first interval of time Δt1 to form the first impurity region D1 of FIG. 2, and the n-type impurity may be introduced for the second interval of time Δt2 to form the second impurity region D2. Since the impurities may be spread to predetermined distances, the first and second intervals of time Δt1 and Δt2 may not accurately correspond to thicknesses of the first and second impurity regions D1 and D2.

Referring to FIG. 7B, a flow diagram of impurities introduced into the clad layer 204 is illustrated. Comparing with the embodiment of FIG. 7A, the embodiment of FIG. 7B is identical to the case of FIG. 7A in terms of the introduction of the n-type impurity. However, the p-type impurity may be only introduced once for the first interval of time Δt1 after the n-type impurity has been introduced once in the embodiment of FIG. 7B. The p-type impurity may be introduced for the first interval of time Δt1 to form the doped impurity region D1a among four first impurity regions D1 shown in FIG. 4, the doped p-type impurity may be spread to form the undoped impurity region D1b, and the n-type impurity may be introduced for the second interval of time Δt2 to form the second impurity region D2.

In the case of the semiconductor light emitting device in which the p-type semiconductor layer formed through a flow of impurities introduction is employed, it was confirmed that luminance thereof increases by approximately 3% as compared to the case of a semiconductor light emitting device having no n-type impurity introduced therein.

Referring to FIG. 7C, a flow diagram of impurities introduced into the p-type semiconductor layer 304 is illustrated. Compared with the embodiment of FIG. 7A, the embodiment of FIG. 7C is identical to the case of FIG. 7A in terms of the introduction of the n-type impurity. However, the p-type impurity may be continuously introduced for a third interval of time Δt3 during which the p-type semiconductor layer 304 is formed, in the embodiment of FIG. 7C. During the introduction of the p-type impurity, the n-type impurity may be introduced for the second interval of time Δt2 to form the second impurity region D2′ of FIG. 6 and the remaining region may form the first impurity region D1.

FIG. 8 is a cross-sectional view illustrating a semiconductor light emitting device according to an embodiment of the present inventive concept.

Referring to FIG. 8, in a semiconductor light emitting device 400 according to an embodiment of the present inventive concept, a p-type contact layer 405 may be formed above a conductive substrate 409, and on the p-type contact layer 405, a light emitting structure including a p-type semiconductor layer 404, an active layer 403, and an n-type semiconductor layer 402 may be formed. An n-type contact layer 408 may be formed between the p-type contact layer 405 and the conductive substrate 409 and be electrically connected to the n-type semiconductor layer 402 through a conductive via V. The p-type contact layer 405 and the n-type contact layer 408 may be electrically isolated from each other and to this end, an insulating layer 420 may be interposed therebetween. A p-type electrode 407 may be disposed on an exposed upper surface of the p-type contact layer 405.

The conductive substrate 409 may serve as a support supporting the light emitting structure when a process such as a laser lift off process or the like is performed in order to remove a semiconductor growth substrate. The conductive substrate 409 may itself serve as an electrode of the semiconductor light emitting device. In this case, the conductive substrate 409 may be formed of a material including one of Au, Ni, Al, Cu, W, Si, Se and GaAs, for example, may be a material formed by doping a silicon (Si) substrate with aluminum (Al). According to an embodiment of the present inventive concept, an insulating substrate may be used instead of the conductive substrate 409 and in this case, a portion of the n-type contact layer 408 may be exposed and a separate n-type electrode or pad may be formed on the exposed portion of the n-type contact layer 408. The insulating substrate may be used by selecting an appropriate material having excellent heat radiation characteristics or a coefficient of thermal expansion slightly different from heat radiation characteristics or a coefficient of thermal expansion of a material forming the light emitting structure. Further, the insulating substrate may be formed of a material requiring a low unit cost. For examples, alumina, AlN, undoped silicon or the like may satisfy the above conditions.

The p-type semiconductor layer 404 may have one of the structures as described with reference to FIGS. 2, 5 and 6. Accordingly, the p-type semiconductor layer 404 may include at least one n-type impurity region.

The p-type contact layer 405 may serve to reflect light emitted from the active layer 403 upwardly of the semiconductor light emitting device 400, that is, in a direction toward the n-type semiconductor layer 402. Further, the p-type contact layer 405 may be in ohmic contact with the p-type semiconductor layer 404. The p-type contact layer 405 may include Ag, Ni, Al, Rh, Pd, Ir, Ru, Mg, Zn, Pt, Au or the like.

The n-type contact layer 408 may be similar to the p-type contact layer 405 in terms of the function and composite materials thereof. The conductive via V may be connected to the n-type semiconductor layer 402, and the amount, shape, pitch and contact area thereof with the n-type semiconductor layer 402 may be appropriately adjustable. According to an embodiment of the present inventive concept, a region of the conductive via V contacting the n-type semiconductor layer 402 may be formed using a material in ohmic contact with the n-type semiconductor layer 402, such that the region of the conductive via V contacting the n-type semiconductor layer 402 may be formed of a different material from a material of the remaining region thereof.

The insulating layer 420 may be formed of any material as long as it may have electrical insulating properties, but the material may absorb light in a very small amount. Thus, a silicon oxide or a silicon nitride such as SiO₂, SiO_{X}N_{Y}, Si_{X}N_{Y} or the like may be used.

Since the semiconductor light emitting device 400 according to an embodiment of the present inventive concept may include the n-type impurity region, the hole concentration may be increased to improve internal quantum efficiency. Furthermore, it may not necessary to form a separate electrode on the upper surface of the n-type semiconductor layer 402 due to the use of the conductive via V, and thus the quantity of light emitted to the upper surface of the n-type semiconductor layer 402 may be increased.

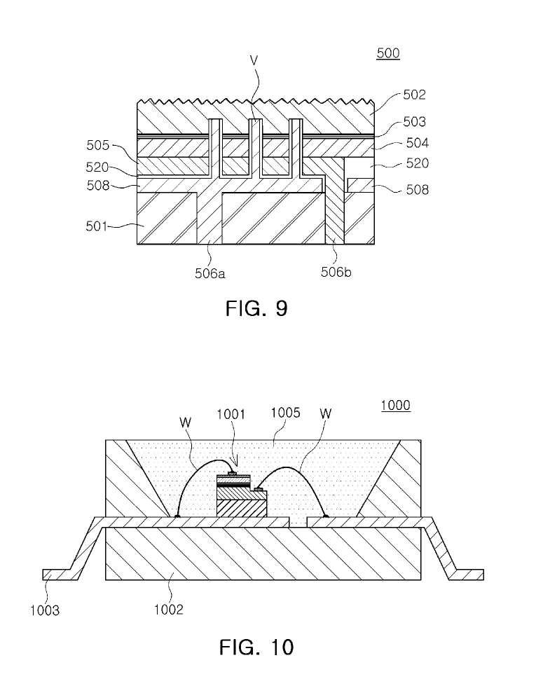

FIG. 9 is a cross-sectional view illustrating a semiconductor light emitting device according to an embodiment of the present inventive concept.

Referring to FIG. 9, in a semiconductor light emitting device 500 according to an embodiment of the present inventive concept, a p-type contact layer 505 may be formed above a substrate 501, and on the p-type contact layer 505, a light emitting structure including a p-type semiconductor layer 504, an active layer 503, and an n-type semiconductor layer 502 may be formed. An n-type contact layer 508 may be formed between the p-type contact layer 505 and the substrate 501 and be electrically connected to the n-type semiconductor layer 502 through the conductive via V. The p-type contact layer 505 and the n-type contact layer 508 may be electrically isolated from each other, and to this end, an insulating layer 520 may be interposed therebetween.

The p-type semiconductor layer 504 may have one of the structures as described with reference to FIGS. 2, 5 and 6. Accordingly, the p-type semiconductor layer 504 may include at least one n-type impurity region.

A surface of the n-type semiconductor layer 502 may be uneven or rough. For example, the unevenness or roughness may be obtained by wet etching the n-type semiconductor layer 502 after removing a semiconductor growth substrate from the light emitting structure.

In an embodiment of the present inventive concept, the n-type contact layer 508 may include a first electrode part 506a extended in a direction toward the substrate 501 and exposed to the outside and similarly to this, the p-type contact layer 505 may include a second electrode part 506b extended in the direction toward the substrate 501 and exposed to the outside. In order to obtain such a structure, the p-type contact layer 505 may be formed to pass through a through hole formed in the n-type contact layer 508.

In the semiconductor light emitting device 500 according to an embodiment of the present inventive concept, since the p-type semiconductor layer 502 may include the n-type impurity region, the hole concentration may be increased to improve internal quantum efficiency. Further, the electrode parts may be exposed through a lower portion of the semiconductor light emitting device 500, such that the semiconductor light emitting device 500 may be directly mounted on a substrate, a lead frame or the like. Furthermore, a conductive wire is not used to provide advantages in terms of reliability, light extraction efficiency, and process convenience.

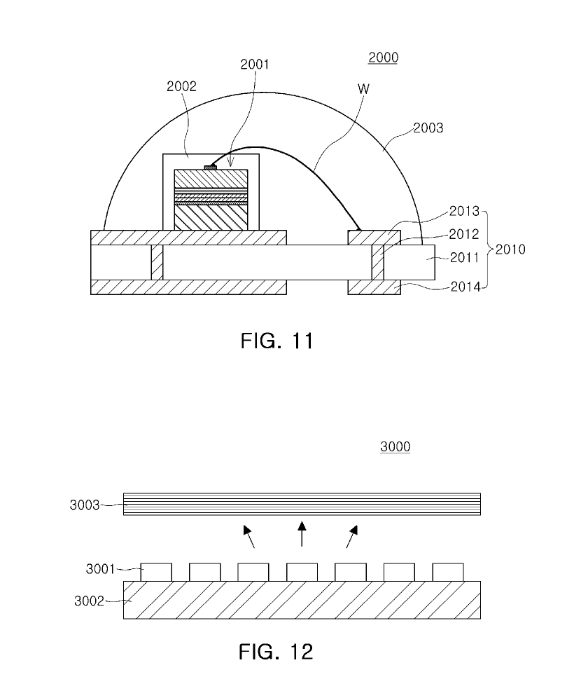

FIGS. 10 and 11 are views respectively illustrating an example of applying the semiconductor light emitting device according to an embodiment of the present inventive concept to a package.

Referring to FIG. 10, a semiconductor light emitting device package 1000 may include a semiconductor light emitting device 1001, a package main body 1002 and a pair of lead frames 1003. The semiconductor light emitting device 1001 may be mounted on the lead frame 1003 to be electrically connected thereto through a wire W. According to an embodiment of the present inventive concept, the semiconductor light emitting device 1001 may be mounted on another portion of the package 1000 rather than the lead frame 1003, for example, on the package main body 1002. The package main body 1002 may have a cup shape in order to improve light reflection efficiency, and such a reflective cup may be filled with a sealing member 1005 including a light transmissive material in order to encapsulate the semiconductor light emitting device 1001 and the wire W. Although FIG. 10 illustrates the case in which the semiconductor light emitting device package 1000 includes the semiconductor light emitting device 100 of FIG. 1, the semiconductor light emitting device package 1000 may include any one of the semiconductor light emitting devices 200, 300, 400 and 500 of FIGS. 3, 5, 8, and 9 according to an embodiment of the present inventive concept.

Referring to FIG. 11, a semiconductor light emitting device package 2000 may include a semiconductor light emitting device 2001, a mounting board 2010 and a sealing member 2003. In addition, a wavelength conversion part 2002 may be formed on upper and side surfaces of the semiconductor light emitting device 2001. The semiconductor light emitting device 2001 may be mounted on the mounting board 2010 and electrically connected thereto through a wire W and the conductive substrate 209 (refer to FIG. 3).

The mounting board 2010 may include a substrate main body 2011, an upper surface electrode 2013, and a lower surface electrode 2014. In addition, the mounting board 2010 may also include a through electrode 2012 connecting the upper surface electrode 2013 and the lower surface electrode 2014. The mounting board 2010 may be provided as a board such as PCB, MCPCB, MPCB, FPCB or the like and a structure thereof may be used in various manners.

The wavelength conversion part 2002 may include fluorescent materials or quantum dots. The sealing member 2003 may have a convex lens shape in which an upper surface thereof is upwardly convex, but may have a concave lens shape, whereby an orientation angle of light emitted through an upper surface of the sealing member 2003 may be controlled.

Although FIG. 11 illustrates the case in which the semiconductor light emitting device package 2000 includes the semiconductor light emitting device 200 of FIG. 3, the semiconductor light emitting device package 2000 may include any one of the semiconductor light emitting devices 100, 300, 400 and 500 of FIGS. 1, 5, 8, and 9 according to an embodiment of the present inventive concept.

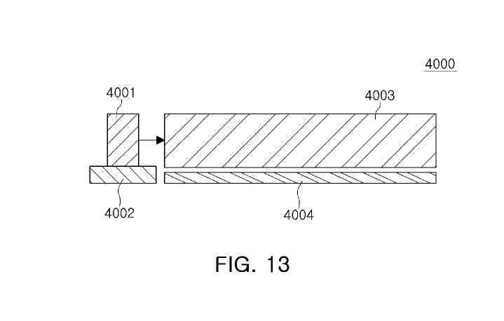

FIGS. 12 and 13 are views respectively illustrating an example of applying the semiconductor light emitting device according to an embodiment of the present inventive concept to a backlight unit.

Referring to FIG. 12, a backlight unit 3000 may include a light source 3001 mounted on a substrate 3002 and at least one optical sheet 3003 disposed thereabove. The light source 3001 may be a semiconductor light emitting device package having the structure above-described with reference to FIGS. 10 and 11 or a structure similar thereto. Alternatively, a semiconductor light emitting device may be directly mounted on the substrate 3002 in a chip-on-board (COB) scheme.

The light source 3001 in the backlight unit 3000 of FIG. 12 emits light toward a liquid crystal display (LCD) device disposed thereabove. On the other hand, alight source 4001 mounted on a substrate 4002 in a backlight unit 4000 of FIG. 13 emits light laterally and the emitted light is incident to a light guide plate 4003 such that the backlight unit 4000 may serve as a surface light source. The light that has passed through the light guide plate 4003 may be emitted upwardly and a reflective layer 4004 may be formed under a bottom surface of the light guide plate 4003 in order to improve light extraction efficiency.

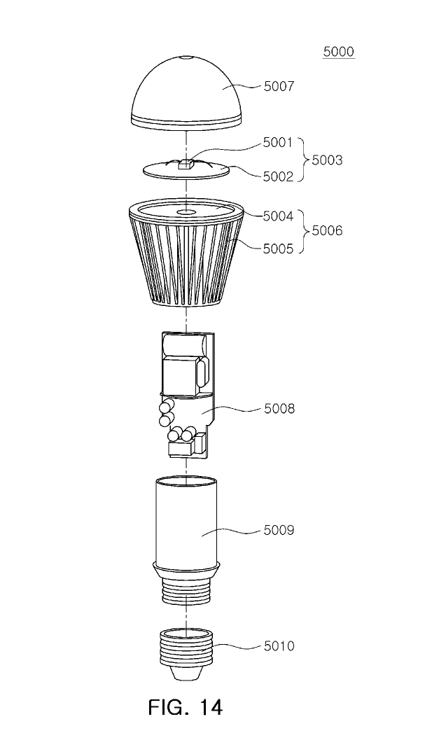

FIG. 14 is a view illustrating an example of applying a semiconductor light emitting device according to an embodiment of the present inventive concept to a lighting device.

Referring to an exploded perspective view of FIG. 14, a lighting device 5000 is exemplified as a bulb-type lamp, and includes a light emitting module 5003, a driving unit 5008 and an external connector unit 5010. In addition, exterior structures such as an external housing 5006, an internal housing 5009, a cover unit 5007 and the like may be additionally included. The light emitting module 5003 may include one semiconductor light emitting device 5001, which may be one of the semiconductor light emitting devices of FIGS. 1, 3, 5, 8, and 9, and a circuit board 5002 having the semiconductor light emitting device 5001 mounted thereon. FIG. 14 illustrates the case in which a single semiconductor light emitting device 5001 is mounted on the circuit board 5002; however, if necessary, a plurality of semiconductor light emitting devices may be mounted thereon. In addition, the semiconductor light emitting device 5001 may be manufactured in the form of a package and then mounted on the circuit board 5002, rather than being directly mounted thereon.

In the lighting device 5000, the light emitting module 5003 may include the external housing 5006 serving as a heat radiating part, and the external housing 5006 may include a heat sink plate 5004 in direct contact with the light emitting module 5003 to improve the dissipation of heat and a plurality of heat radiating fins 5005. In addition, the lighting device 5000 may include the cover unit 5007 disposed above the light emitting module 5003 and having a convex lens shape. The driving unit 5008 may be disposed inside the internal housing 5009 and connected to the external connector unit 5010 such as a socket structure to receive power from an external power source. In addition, the driving unit 5008 may convert the received power into a current source appropriate for driving the semiconductor light emitting device 5001 of the light emitting module 5003 and supply the converted current source thereto. For example, the driving unit 5008 may be provided as an AC-DC converter, a rectifying circuit part, or the like.

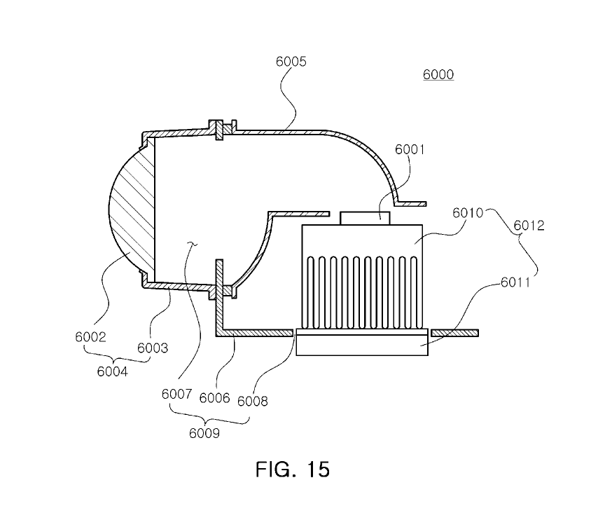

FIG. 15 is a view illustrating an example of applying a semiconductor light emitting device according to an embodiment of the present inventive concept to a headlamp.

Referring to FIG. 15, a headlamp 6000 used as a vehicle lighting element or the like may include a light source 6001, a reflective unit 6005 and a lens cover unit 6004, the lens cover unit 6004 including a hollow guide part 6003 and a lens 6002. In addition, the head lamp 6000 may further include a heat radiating unit 6012 dissipating heat generated by the light source 6001 outwardly. The heat radiating unit 6012 may include a heat sink 6010 and a cooling fan 6011 in order to effectively dissipate heat. In addition, the headlamp 6000 may further include a housing 6009 including a housing body 6006 allowing the heat radiating unit 6012 and the reflective unit 6005 to be fixed thereto and supported thereby. One surface of the housing 6009 may be provided with a central hole 6008 into which the heat radiating unit 6012 is inserted to be coupled thereto. In addition, the other surface of the housing 6009 integrally connected to and bent in a direction perpendicular to one surface of the housing 6009 may be provided with a forward hole 6007 such that the reflective unit 6005 may be disposed above the light source 6001. Accordingly, a forward side may be opened by the reflective unit 6005 and the reflective unit 6005 may be fixed to the housing 1009 such that the opened forward side corresponds to the forward hole 6007, whereby light reflected by the reflective unit 6005 disposed above the light source 6001 may pass through the forward hole 6007 to be emitted outwardly.

As set forth above, according to embodiments of the present inventive concept, a semiconductor light emitting device having improved luminance through an improvement in internal quantum efficiency can be provided.

While the present inventive concept has been shown and described in connection with the embodiments, it will be apparent to those skilled in the art that modifications and variations can be made without departing from the spirit and scope of the present inventive concept as defined by the appended claims.

What is claimed is:

1. A semiconductor light emitting device, comprising:
an n-type semiconductor layer;
a p-type semiconductor layer including a first impurity region including a p-type impurity and a second impurity region including an n-type impurity, the first and second impurity regions being alternately repeated at least once; and
an active layer interposed between the n-type semiconductor layer and the p-type semiconductor layer.

2. The semiconductor light emitting device of claim 1, wherein:
the second impurity region further includes the p-type impurity, and
a concentration of the p-type impurity in the p-type semiconductor layer is uniform or gradually varied.

3. The semiconductor light emitting device of claim 2, wherein a concentration of the p-type impurity included in the second impurity region is higher than a concentration of the n-type impurity included in the second impurity region.

4. The semiconductor light emitting device of claim 1, wherein:
the first impurity region includes four first impurity sub-regions, and
the second impurity region includes three second impurity sub-regions.

5. The semiconductor light emitting device of claim 1, wherein the first impurity region includes a plurality of first impurity sub-regions that include intentionally doped and intentionally undoped impurity regions.

6. The semiconductor light emitting device of claim 5, wherein:
the first impurity region includes four first impurity sub-regions, and
the first impurity sub-region disposed to be second from the active layer among the four first impurity sub-regions is the intentionally doped impurity region, and remaining first impurity sub-regions among the four first impurity sub-regions are the intentionally undoped impurity regions.

7. The semiconductor light emitting device of claim 1, wherein the second impurity region includes the n-type impurity in a concentration of 1.0×10¹⁶/cm³ to 1.0×10¹⁸/cm³.

8. The semiconductor light emitting device of claim 1, wherein the first impurity region has a first thickness and the second impurity region has a second thickness ranging from 2% to 10% of the first thickness.

9. The semiconductor light emitting device of claim 1, wherein the first impurity region and the second impurity region are formed of AlₓIn_{y}Ga_{1-x-y}N (0≦x<1, 0≦y<1).

10. The semiconductor light emitting device of claim 1, wherein the first impurity region and the second impurity region have the same band gap energy.

11. The semiconductor light emitting device of claim 1, wherein:
the n-type impurity is at least one of silicon (Si) and carbon (C), and
the p-type impurity is at least one of magnesium (Mg) and zinc (Zn).

12. The semiconductor light emitting device of claim 1, wherein the p-type semiconductor layer further includes an electron blocking layer disposed to be adjacent to the active layer and having a band gap energy higher than a band gap energy of the first impurity region and the second impurity region.

13. The semiconductor light emitting device of claim 12, wherein the electron blocking layer includes a region formed of AlₓIn_{y}Ga_{1-x-y}N (0<x≦1, 0≦y<1).

14. A semiconductor light emitting device, comprising:
an n-type semiconductor layer;
a p-type semiconductor layer including a plurality of n-type impurity regions spaced apart from each other by a predetermined interval, the p-type semiconductor layer having a gradually varied p-type impurity concentration; and
an active layer interposed between the n-type semiconductor layer and the p-type semiconductor layer.

15. The semiconductor light emitting device of claim 14, wherein in the plurality of n-type impurity regions, a concentration of an n-type impurity ranges from 1.0×10¹⁶/cm³ to 1.0×10¹⁸/cm³.

16. The semiconductor light emitting device of claim 14, wherein the p-type semiconductor layer includes a plurality of p-type impurity regions spaced apart from each other by a predetermined interval.

17. The semiconductor light emitting device of claim 16, wherein each of the p-type impurity regions has a thickness greater than a thickness of each of the second impurity regions.

18. A lighting device, comprising:
a light emitting module including a circuit board and a light emitting device disposed on the circuit board; and
a heat sink plate in direct contact with the light emitting module,
wherein the light emitting device includes:
an n-type semiconductor layer,
a p-type semiconductor layer including a first impurity region including a p-type impurity and a second impurity region including an n-type impurity, the first and second impurity regions being alternately repeated at least once, and
an active layer interposed between the n-type semiconductor layer and the p-type semiconductor layer.

19. The lighting device of claim 18, further comprising a plurality of heat radiating fins.

20. The lighting device of claim 18, the light emitting device is disposed on the circuit board in the form of a package.
